(19) United States
(12) Patent Application Publication
(10) Pub. No.: US 2026/0372122 A1
(43) Pub. Date: Nov. 19, 2026

(54) SEMICONDUCTOR DEVICE

(71) Applicant: FUJI ELECTRIC CO., LTD., Kawasaki-shi (JP)

(72) Inventors: Norihiro DAICHO, Matsumoto-city (JP); Yoshihiro KODAIRA, Matsumoto-city (JP)

(73) Assignee: FUJI ELECTRIC CO., LTD., Kawasaki-shi (JP)

(21) Appl. No.: 19/578,742

(22) Filed: Mar. 25, 2026

(30) Foreign Application Priority Data
May 16, 2025 (JP) 2025-082943

(51) Int. Cl. H10W 70/40

(52) U.S. Cl. CPC H10W 70/429; H10W 70/465; H10W 70/468

(57) ABSTRACT

A semiconductor device, having: first and second boards each having an upper surface; a case which includes side walls that surround an opening in a plan view, and include first and second side walls each extending in a longitudinal direction, the first and second boards being disposed in the case sequentially in the longitudinal direction; an external connection terminal which has a lower end electrically connected to the second board, and has, at an upper end thereof, an external connection portion facing the second board; a first nut housing portion, which is attached to the case in a thickness direction of the case, and is positioned above the opening and faces the first board; and a second nut housing portion, which is attached to the case in the longitudinal direction and located between the first and second side walls, and is provided on the external connection portion.

### CROSS-REFERENCE TO RELATED APPLICATIONS

This application is based upon and claims the benefit of priority of the prior Japanese Patent Application No. 2025-082943, filed on May 16, 2025, the entire contents of which are incorporated herein by reference.

### BACKGROUND OF THE INVENTION

### 1. Field of the Invention

The embodiments discussed herein relate to a semiconductor device.

### 2. Background of the Related Art

An external lead frame as a main terminal of a semiconductor device is fastened by a nut and a bolt. A terminal block in which the nut is housed is housed below the main terminal (see, for example, International Publication Pamphlet No. WO 2024/171848). Alternatively, the nut is housed in a recess formed in a portion facing the lower surface of the main terminal (for example, Japanese Laid-open Patent Publication No. 2013-065598, International Publication Pamphlet No. WO 2018/135176, and International Publication Pamphlet No. WO 2016/059916).

### SUMMARY OF THE INVENTION

According to an aspect of the present disclosure, there is provided a semiconductor device, including: a first board having an upper surface; a second board having an upper surface; a case which includes side walls that surround an opening in a plan view of the semiconductor device, and include a first side wall and a second side wall each extending in a longitudinal direction, the first board and the second board being disposed in the case sequentially in the longitudinal direction; an external connection terminal which has a lower end electrically connected to the second board, and has, at an upper end thereof, an external connection portion facing the second board; a first nut housing portion, which is attached to the first side wall and the second side wall in a thickness direction of the case, and is positioned above the opening and faces the first board; and a second nut housing portion, which is attached to the case in the longitudinal direction and located between the first side wall and the second side wall, and is provided on the external connection portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a flowchart illustrating a method of manufacturing the semiconductor device according to the first embodiment;

FIG. 4 is a plan view illustrating a mounting step included in the method of manufacturing the semiconductor device according to the first embodiment;

FIG. 5 is a cross-sectional view illustrating the mounting step included in the method of manufacturing the semiconductor device according to the first embodiment;

FIG. 6 is a plan view illustrating a case attachment step included in the method of manufacturing the semiconductor device according to the first embodiment;

FIG. 7 is a cross-sectional view illustrating the case attachment step included in the method of manufacturing the semiconductor device according to the first embodiment;

FIG. 8 is a plan view illustrating a nut housing portion attachment (vertical direction) step included in the method of manufacturing the semiconductor device according to the first embodiment;

FIG. 9 is a cross-sectional view illustrating the nut housing portion attachment (vertical direction) step included in the method of manufacturing the semiconductor device according to the first embodiment;

FIG. 10 is a plan view illustrating a terminal unit attachment step included in the method of manufacturing the semiconductor device according to the first embodiment;

FIG. 11 is a first cross-sectional view illustrating the terminal unit attachment step included in the method of manufacturing the semiconductor device according to the first embodiment;

FIG. 12 is a second cross-sectional view illustrating the terminal unit attachment step included in the method of manufacturing the semiconductor device according to the first embodiment;

FIG. 13 is a plan view illustrating a main terminal attachment step included in the method of manufacturing the semiconductor device according to the first embodiment;

FIG. 14 is a cross-sectional view illustrating the main terminal attachment step included in the method of manufacturing the semiconductor device according to the first embodiment;

FIGS. 15A and 15B illustrate a second nut housing portion included in the semiconductor device according to the first embodiment;

FIG. 16 is a cross-sectional view (part 1) illustrating a nut housing portion attachment (horizontal direction) step included in the method of manufacturing the semiconductor device according to the first embodiment;

FIG. 17 is a cross-sectional view (part 2) illustrating the nut housing portion attachment (horizontal direction) step included in the method of manufacturing the semiconductor device according to the first embodiment;

FIG. 18 is a cross-sectional view (part 3) illustrating the nut housing portion attachment (horizontal direction) step included in the method of manufacturing the semiconductor device according to the first embodiment; and

FIG. 19 is a plan view of a semiconductor device according to a second embodiment.

### DETAILED DESCRIPTION OF THE INVENTION

Hereinafter, embodiments will be described with reference to the drawings. Throughout the following embodiments, the term “upper surface” refers to a surface facing upward when viewed on the page. Similarly, “upper”, “top”, and “above” refer to the upward direction when viewed on the page. In addition, the term “lower surface” refers to a surface facing downward when viewed on the page. Similarly, “lower”, “bottom”, and “below” refer to the downward direction when viewed on the page. These directions refer to their respective directions in all drawings. The terms “upper surface”, “upper”, “top”, “above”, “lower”, “lower surface”, “bottom”, and “below” are merely convenient expressions for determining a relative positional relationship, and do not limit the technical spirit of the present disclosure. In addition, throughout the following embodiments, the term “main component” refers to a case of containing 80 vol% or more. Similarly, “substantially the same” may be within a range of ±10%. The terms “perpendicular”, “orthogonal”, and “parallel” may be within a range of ±10°.

### First Embodiment

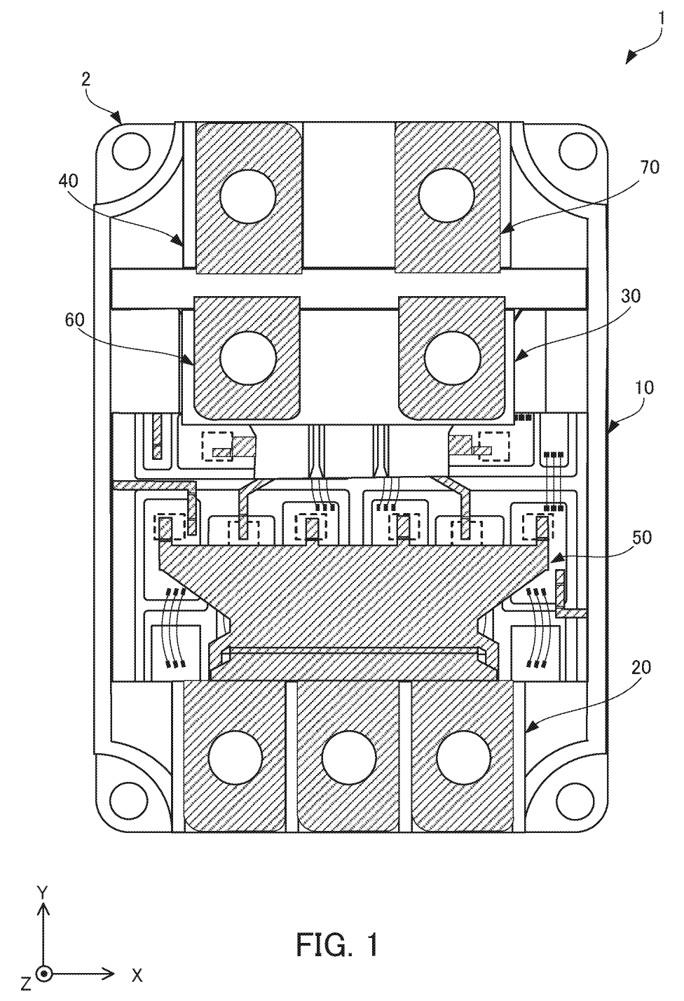

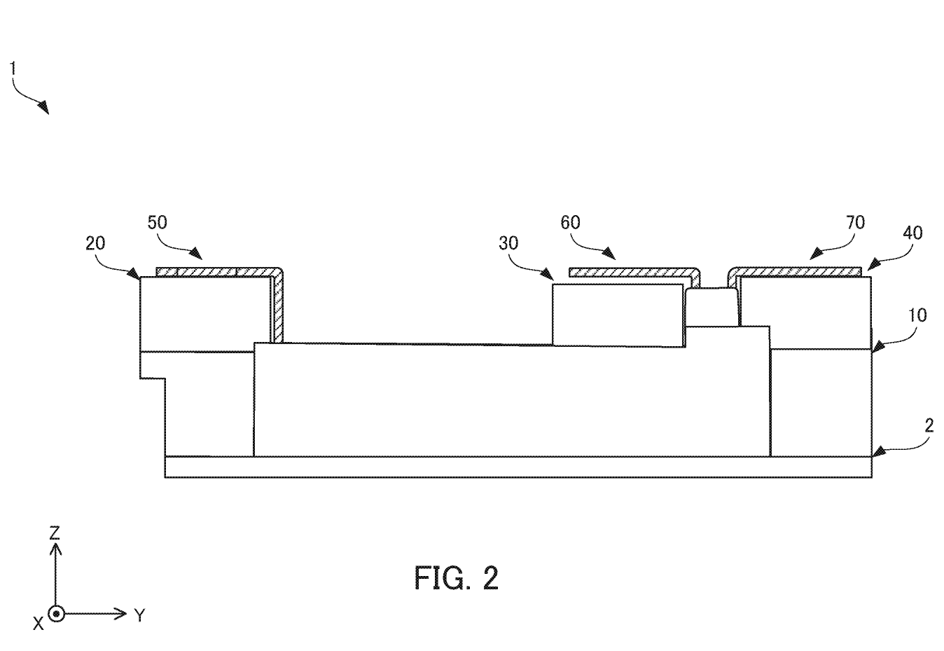

A semiconductor device according to a first embodiment will be described with reference to FIGS. 1 and 2. FIG. 1 is a plan view of a semiconductor device according to a first embodiment. FIG. 2 is a side view of the semiconductor device according to the first embodiment. FIG. 2 is a side view of this semiconductor device 1 in FIG. 1 when viewed from the right side of FIG. 1.

The semiconductor device 1 includes a heat dissipation base 2, a case 10, a first nut housing portion 20, a second nut housing portion 30, and a third nut housing portion 40. The heat dissipation base 2 has a rectangular shape in plan view. The heat dissipation base 2 is formed of a metal having excellent heat dissipation properties. The metal may be, for example, copper, aluminum, or an alloy containing at least one of these metals. In order to improve the corrosion resistance, the surface of the heat dissipation base 2 may be plated. Examples of the plating material include nickel, a nickel-phosphorus alloy, and a nickel-boron alloy. Insulating circuit boards to be described below are mounted on the heat dissipation base 2. Details of the heat dissipation base 2 will be described below.

The case 10 has a rectangular frame shape in plan view. The case 10 is disposed at the edge of the heat dissipation base 2 and surrounds the insulating circuit boards disposed on the heat dissipation base 2. The case 10 and the heat dissipation base 2 may be bonded by an adhesive.

Each of the first nut housing portion 20, the second nut housing portion 30, and the third nut housing portion 40 may have a block shape. The first nut housing portion 20, the second nut housing portion 30, and the third nut housing portion 40 face the heat dissipation base 2 (the insulating circuit boards mounted on the heat dissipation base 2) and are attached to the case 10.

The first nut housing portion 20 and the third nut housing portion 40 are attached to both short sides of the case 10. The second nut housing portion 30 is attached to the case 10 between the first nut housing portion 20 and the third nut housing portion 40. Details of the case 10, the first nut housing portion 20, the second nut housing portion 30, and the third nut housing portion 40 will be described below.

A first external connection terminal 50 is provided in the first nut housing portion 20 and the case 10. A second external connection terminal 60 is provided in the second nut housing portion 30 and the case 10. A third external connection terminal 70 is provided in the third nut housing portion 40 and the case 10. The second external connection terminal 60 and the third external connection terminal 70 are integrated by resin. Details of the first external connection terminal 50, the second external connection terminal 60, and the third external connection terminal 70 will be described below.

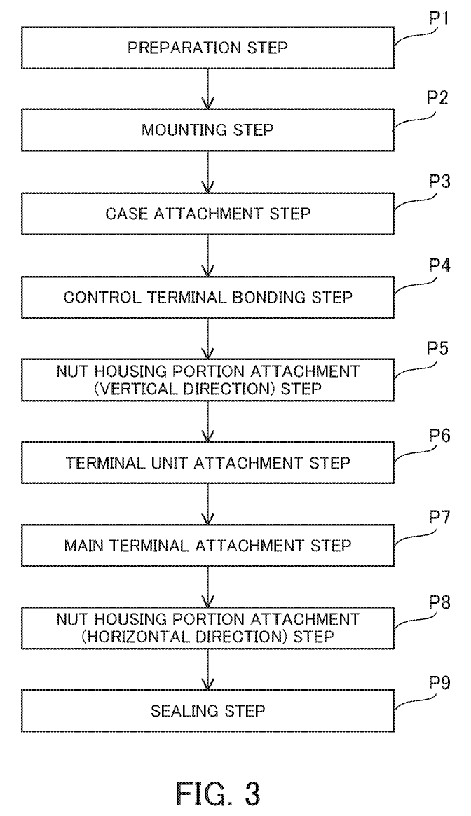

Next, a method of manufacturing the semiconductor device 1 will be described with reference to FIG. 3. FIG. 3 is a flowchart illustrating a method of manufacturing the semiconductor device according to the first embodiment. First, a preparation step of preparing components of the semiconductor device 1 is performed (step P1). Examples of the components include the heat dissipation base 2, the insulating circuit boards (described below), semiconductor chips (described below), the case 10, the first nut housing portion 20, the second nut housing portion 30, the third nut housing portion 40, a terminal unit (described below) including the first external connection terminal 50, the second external connection terminal 60, and the third external connection terminal 70. The case 10, the first nut housing portion 20, the second nut housing portion 30, and the third nut housing portion 40 may be molded in advance. The terminal unit including the second external connection terminal 60 and the third external connection terminal 70 may also be molded in advance.

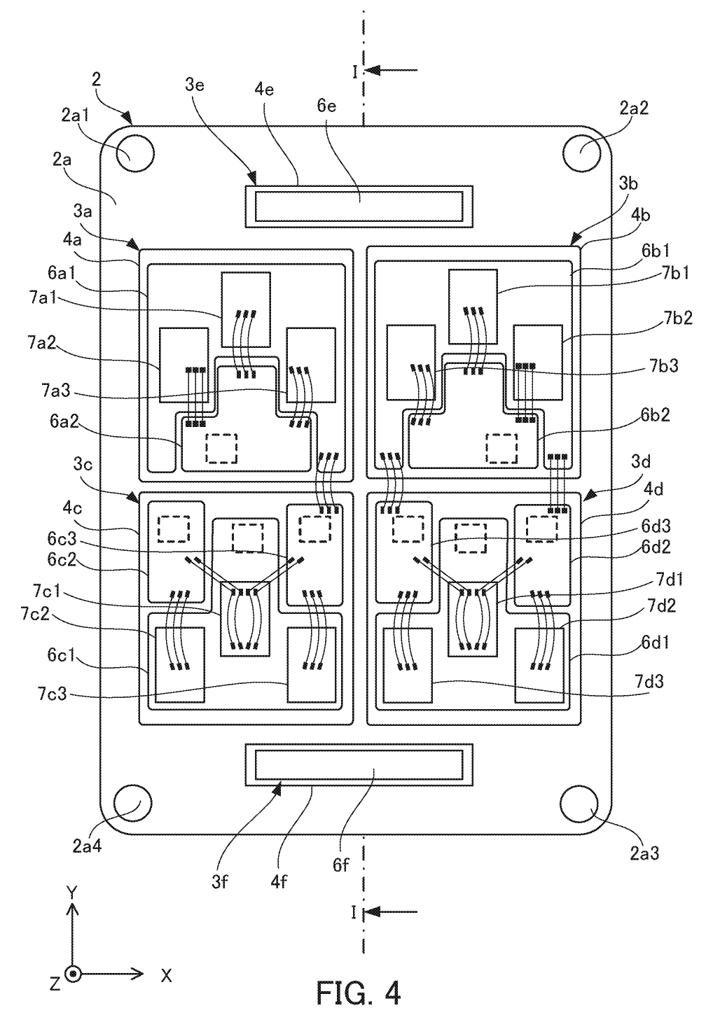

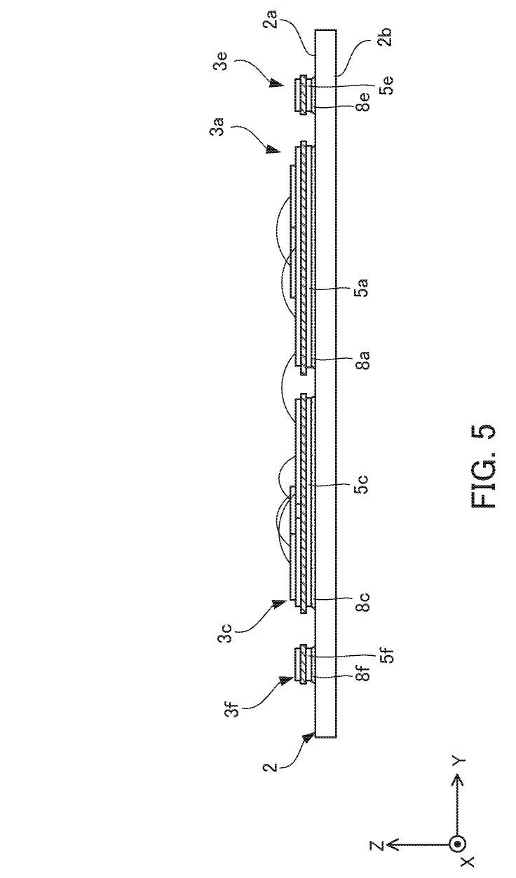

Next, a mounting step of mounting the insulating circuit boards on the heat dissipation base 2 is performed (step P2). This mounting step will be described with reference to FIGS. 4 and 5. FIG. 4 is a plan view illustrating the mounting step included in the method of manufacturing the semiconductor device according to the first embodiment. FIG. 5 is a cross-sectional view illustrating the mounting step included in the method of manufacturing the semiconductor device according to the first embodiment. FIG. 5 is a cross-sectional view taken along a dashed-dotted line I-I in FIG. 4.

In step P2, first, semiconductor chips 7a1, 7a2, and 7a3 are mounted on an insulating circuit board 3a via bonding members. Similarly, semiconductor chips 7b1, 7b2, and 7b3 are mounted on an insulating circuit board 3b via bonding members. Semiconductor chips 7c1, 7c2, and 7c3 are mounted on an insulating circuit board 3c via bonding members. Semiconductor chips 7d1, 7d2, and 7d3 are mounted on an insulating circuit board 3d via bonding members.

The insulating circuit board 3a on which the semiconductor chips 7a1, 7a2, and 7a3 have been mounted is mounted on an upper surface 2a of the heat dissipation base 2 via a bonding member 8a. Similarly, the insulating circuit board 3b on which the semiconductor chips 7b1, 7b2, and 7b3 have been mounted is mounted on the upper surface 2a of the heat dissipation base 2 via a bonding member (not illustrated). The insulating circuit board 3c on which the semiconductor chips 7c1, 7c2, and 7c3 have been mounted is mounted on the upper surface 2a of the heat dissipation base 2 via a bonding member 8c. The insulating circuit board 3d on which the semiconductor chips 7d1, 7d2, and 7d3 have been mounted is mounted on the upper surface 2a of the heat dissipation base 2 via a bonding member (not illustrated).

The insulating circuit board 3a and the semiconductor chips 7a1, 7a2, and 7a3 are electrically connected by wirings. The insulating circuit board 3b and the semiconductor chips 7b1, 7b2, and 7b3 are electrically connected by wirings. The insulating circuit board 3c and the control electrodes of the semiconductor chips 7c1, 7c2, and 7c3 are electrically connected by wirings (not illustrated). The insulating circuit board 3d and the control electrodes of the semiconductor chips 7d1, 7d2, and 7d3 are electrically connected by wirings (not illustrated).

Similarly, an insulating circuit board 3e is mounted on the upper surface 2a of the heat dissipation base 2 via a bonding member 8e. An insulating circuit board 3f (first board) is mounted on the upper surface 2a of the heat dissipation base 2 via a bonding member 8f. Wirings for the insulating circuit boards 3e and 3f are not illustrated.

The insulating circuit boards 3a, 3b, 3c, and 3d are mounted on the central portion of the upper surface 2a of the heat dissipation base 2 in two rows and two columns, for example. The insulating circuit board 3e is mounted along a short side (in the +Y direction) of the upper surface 2a of the heat dissipation base 2. The insulating circuit board 3f is mounted along a short side (in the −Y direction) of the upper surface 2a of the heat dissipation base 2.

The heat dissipation base 2 includes the upper surface 2a and a lower surface 2b. The upper surface 2a has a rectangular shape in plan view. The lower surface 2b is opposite to the upper surface 2a, and has the same shape and area as the upper surface 2a. The corner portions of the upper surface 2a and the lower surface 2b may form a right angle. Alternatively, the corner portions of the upper surface 2a and the lower surface 2b may be rounded or chamfered. In the present embodiment, the corner portions of the upper surface 2a and the lower surface 2b are rounded. Fastening holes 2a1, 2a2, 2a3, and 2a4 are formed in the four corners of the heat dissipation base 2. The fastening holes 2a1, 2a2, 2a3, and 2a4 penetrate the upper surface 2a and the lower surface 2b. The fastening holes 2a1, 2a2, 2a3, and 2a4 may be cylindrical.

The insulating circuit board 3a (second board) includes an insulating plate 4a, a metal plate 5a, and conductive circuit patterns 6a1 and 6a2. The insulating plate 4a has a flat rectangular shape in plan view. The insulating plate 4a may be made of a ceramic material having good thermal conductivity. The insulating plate 4a may be made of resin. The resin may have low thermal resistance and high insulating properties. Examples of the resin include a thermosetting resin and a thermoplastic resin. Examples of the thermosetting resin include an epoxy resin. Examples of the thermoplastic resin include a polyimide resin. The resin may further contain a filler. The content and material of the filler are selected so as not to increase the thermal resistance of the insulating plate 4a. The filler may be made of at least one of an oxide and a nitride. Examples of the oxide include silicon oxide and aluminum oxide. Examples of the nitride include silicon nitride, aluminum nitride, and boron nitride.

The metal plate 5a has a smaller area than the insulating plate 4a and has a rectangular shape similar to the insulating plate 4a. The corner portions of the metal plate 5a may be rounded or chamfered. The metal plate 5a is formed on the entire back surface of the insulating plate 4a except for the edge portion thereof. The metal plate 5a is mainly made of a metal having excellent thermal conductivity. The metal may be, for example, copper, aluminum, or an alloy containing at least one of these metals. In order to improve the corrosion resistance, the surface of the metal sheet may be plated. Examples of the plating material include nickel and an alloy containing nickel.

The conductive circuit patterns 6a1 and 6a2 are mainly made of a metal having excellent conductivity. This metal is, for example, copper, aluminum, or an alloy containing at least one of these metals as a main component. In order to improve corrosion resistance, the surface of the conductive circuit patterns 6a1 and 6a2 may be plated. Examples of the plating material include nickel and an alloy containing nickel.

The conductive circuit pattern 6a1 has an inverted U-shape in which a recess is formed in plan view, and is disposed on the upper surface of the insulating plate 4a. The conductive circuit pattern 6a2 is formed in the recess of the conductive circuit pattern 6a1. The number, shape, and size of the conductive circuit patterns 6a1 and 6a2 may be appropriately selected according to the design of the semiconductor device 1. The semiconductor chips 7a1, 7a2, and 7a3 are mounted on the conductive circuit pattern 6a1 via a bonding member.

The insulating circuit board 3b (second board) has the same configuration as the insulating circuit board 3a, and includes an insulating plate 4b, a metal plate (not illustrated), and conductive circuit patterns 6b1 and 6b2. The semiconductor chips 7b1, 7b2, and 7b3 are mounted on the conductive circuit pattern 6b1 of the insulating circuit board 3b in the same manner as in the case of the insulating circuit board 3a.

The insulating circuit board 3c includes an insulating plate 4c, a metal plate 5c, and conductive circuit patterns 6c1, 6c2, and 6c3. The insulating plate 4c has the same shape, size, and material as those of the insulating plate 4a. The metal plate 5c has the same shape, size, and material as those of the metal plate 5a.

The conductive circuit patterns 6c1, 6c2, and 6c3 may be made of the same material as the conductive circuit patterns 6a1 and 6a2. The conductive circuit pattern 6c1 has an inverted T shape in plan view, and is formed on the upper surface of the insulating plate 4a. The conductive circuit patterns 6c2 and 6c3 have a rectangular shape in plan view and are formed on both sides of the protruding portion of the conductive circuit pattern 6c1. The number, shape, and size of the conductive circuit patterns 6c1, 6c2, and 6c3 may be appropriately selected according to the design of the semiconductor device 1. The semiconductor chips 7c1, 7c2, and 7c3 are mounted on the conductive circuit pattern 6c1.

The insulating circuit board 3d has the same configuration as the insulating circuit board 3c, and includes an insulating plate 4d, a metal plate (reference numeral omitted), and conductive circuit patterns 6d1, 6d2, and 6d3. The semiconductor chips 7d1, 7d2, and 7d3 are mounted on the conductive circuit pattern 6d1 of the insulating circuit board 3d in the same manner as in the case of the insulating circuit board 3c.

The upper surfaces (first upper surfaces) of the insulating circuit boards 3a, 3b, 3c, and 3d correspond to the upper surfaces of the conductive circuit patterns 6a1 and 6a2, the conductive circuit patterns 6b1 and 6b2, the conductive circuit patterns 6c1, 6c2, and 6c3, and the conductive circuit patterns 6d1, 6d2, and 6d3.

The insulating circuit board 3e includes an insulating plate 4e, a metal plate 5e, and a conductive circuit pattern 6e. The insulating plate 4e may be made of the same material as the insulating plate 4a. The metal plate 5e may be made of the same material as the metal plate 5a. The metal plate 5e may be formed on the lower surface of the insulating plate 4e. The conductive circuit pattern 6e may be made of the same material as the conductive circuit pattern 6a1. The conductive circuit pattern 6e may be formed on the upper surface of the insulating plate 4e. The insulating circuit board 3f has the same configuration as the insulating circuit board 3e, and includes an insulating plate 4f, a metal plate 5f, and a conductive circuit pattern 6f.

For example, a direct copper bonding (DCB) substrate, an active metal brazed (AMB) substrate, or a resin insulating substrate may be used as the insulating circuit boards 3a, 3b, 3c, 3d, 3e, and 3f having the above-described configuration.

The semiconductor chips 7a1, 7a2, and 7a3, the semiconductor chips 7b1, 7b2, and 7b3, the semiconductor chips 7c1, 7c2, and 7c3, and the semiconductor chips 7d1, 7d2, and 7d3 may be of the same type. Hereinafter, the semiconductor chip 7a1 will be described.

The semiconductor chip 7a1 includes a switching element. Examples of the switching element include a reverse-conducting insulated gate bipolar transistor (RC-IGBT). The RC-IGBT is a semiconductor element in which an IGBT and a freewheeling diode (FWD) are configured in anti-parallel in one chip. Examples of the semiconductor material constituting the semiconductor chip 7a1 include silicon. An input electrode (collector electrode) is provided as a main electrode on the lower surface of the semiconductor chip 7a1. A control electrode (gate electrode) and an output electrode (emitter electrode) as a main electrode are provided on the upper surface of the semiconductor chip 7a1. The semiconductor chip 7a1 has a rectangular shape in plan view. The control electrode may be provided along one side of the upper surface of the semiconductor chip 7a1.

In the semiconductor chip 7a1, the semiconductor material of the switching element may be silicon carbide, and the switching element may be a power metal-oxide-semiconductor field-effect transistor (MOSFET). The semiconductor chip 7a1 in this case may also have a rectangular shape in plan view. An input electrode (drain electrode) is provided as a main electrode on the lower surface of the semiconductor chip 7a1. A control electrode (gate electrode) and an output electrode (source electrode) as a main electrode are provided on the upper surface of the semiconductor chip 7a1. The control electrode may be provided along one side of the upper surface of the semiconductor chip 7a1. The power MOSFET may also be a semiconductor element in which a MOSFET and an FWD are configured in anti-parallel in one chip as a switching element.

In the insulating circuit board 3a, the output electrodes of the semiconductor chips 7a1, 7a2, and 7a3 and the conductive circuit pattern 6a2 are electrically connected by bonding wires (reference numerals omitted). Similarly, in the insulating circuit board 3b, the output electrodes of the semiconductor chips 7b1, 7b2, and 7b3 and the conductive circuit pattern 6b2 are electrically connected by bonding wires (reference numerals omitted).

In the insulating circuit board 3c, the output electrodes of the semiconductor chips 7c1 and 7c2 and the conductive circuit pattern 6c2 are electrically connected by bonding wires (reference numerals omitted). The output electrodes of the semiconductor chips 7c1 and 7c3 and the conductive circuit pattern 6c3 are electrically connected by bonding wires (reference numerals omitted).

Similarly, in the insulating circuit board 3d, the output electrodes of the semiconductor chips 7d1 and 7d2 and the conductive circuit pattern 6d2 are electrically connected by bonding wires (reference numerals omitted). The output electrodes of the semiconductor chips 7d1 and 7d3 and the conductive circuit pattern 6d3 are electrically connected by bonding wires (reference numerals omitted).

Examples of the individual bonding member described above include solder and a metal sintered material. As the solder, lead-free solder is used. The lead-free solder contains, for example, an alloy containing at least two of tin, silver, copper, zinc, antimony, indium, and bismuth as a main component. The sintered material used in the metal sintered body is, for example, silver, iron, copper, aluminum, titanium, nickel, tungsten, or molybdenum or powder of an alloy containing any of these materials.

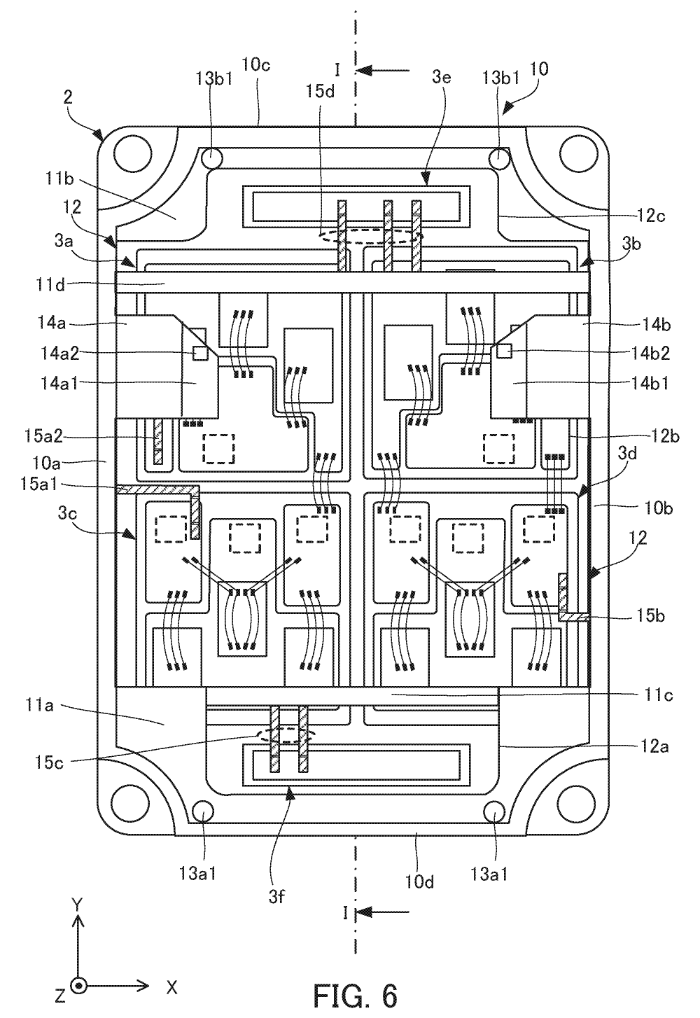

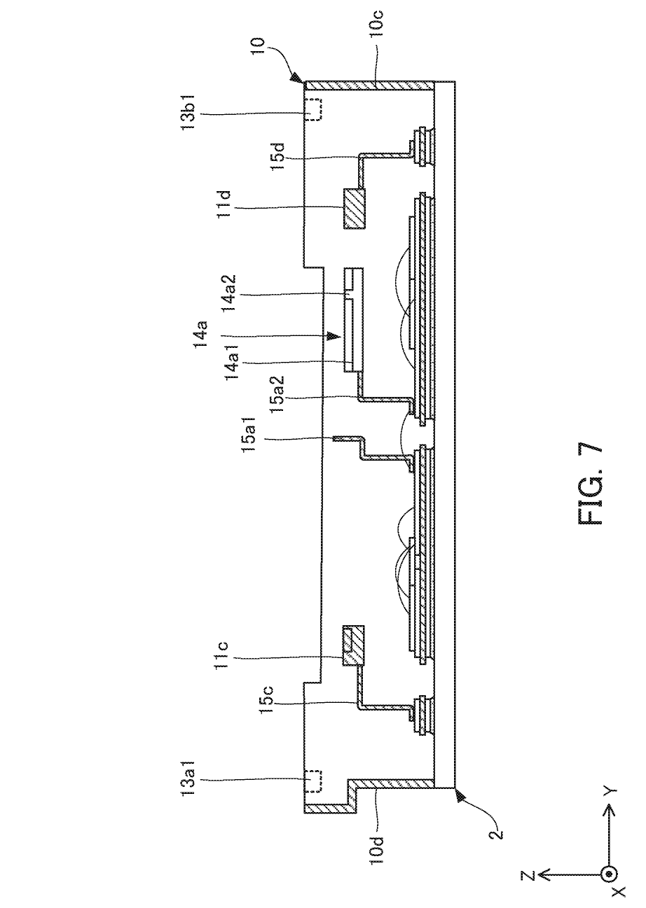

Next, a case attachment step of attaching the case 10 to the heat dissipation base 2 is performed (step P3). The case attachment step will be described with reference to FIGS. 6 and 7. FIG. 6 is a plan view illustrating a case attachment step included in the method of manufacturing the semiconductor device according to the first embodiment. FIG. 7 is a cross-sectional view illustrating the case attachment step included in the method of manufacturing the semiconductor device according to the first embodiment. FIG. 7 is a cross-sectional view taken along a dashed-dotted line I-I in FIG. 6.

The case 10 is attached to an edge portion of the upper surface 2a of the heat dissipation base 2 on which the insulating circuit boards 3a, 3b, 3c, 3d, 3e, and 3f are mounted. An adhesive is applied to the lower end of the case 10 to fix the case 10 to the heat dissipation base 2.

The case 10 has a rectangular shape in plan view. The case 10 includes a first side wall 10a, a second side wall 10b, a third side wall 10c, and a fourth side wall 10d. The first side wall 10a, the second side wall 10b, the third side wall 10c, and the fourth side wall 10d surround four sides of an opening 12. The case 10 includes a first inner edge portion 11a, a second inner edge portion 11b, a first beam portion 11c, a second beam portion 11d, a first positioning member 14a, and a second positioning member 14b.

The first side wall 10a and the third side wall 10c are integrally connected. The third side wall 10c and the second side wall 10b are integrally connected. The second side wall 10b and the fourth side wall 10d are integrally connected. The fourth side wall 10d and the first side wall 10a are integrally connected. Each connection portion may be recessed toward the center of the opening 12 in plan view of the case 10. Thus, the fastening holes 2a1, 2a2, 2a3, and 2a4 of the heat dissipation base 2 are exposed from the corners of the case 10. The first side wall 10a and the second side wall 10b face each other in the longitudinal direction of the case 10, and may have the same shape and the same size. The third side wall 10c and the fourth side wall 10d extend in the width direction of the case 10, and may have the same shape and the same size.

The first inner edge portion 11a is connected to the fourth side wall 10d side of the first side wall 10a, the fourth side wall 10d side of the second side wall 10b, and the fourth side wall 10d. The first inner edge portion 11a may have a flat plate shape, and has a recess recessed toward the fourth side wall 10d in plan view. The first inner edge portion 11a has first attachment parts to which first attachment portions described below are attached. For example, two first holes 13a1 are formed as the first attachment parts. The first holes 13a1 are formed, for example, on the fourth side wall 10d side of the first inner edge portion 11a. The first holes 13a1 are recessed (or penetrate) from the upper surface toward the lower surface of the first inner edge portion 11a. The positions and the number of the first holes 13a1 are merely examples, and the present embodiment is not limited thereto.

The second inner edge portion 11b is connected to the third side wall 10c side of the first side wall 10a, the third side wall 10c side of the second side wall 10b, and the third side wall 10c. The second inner edge portion 11b may have a flat plate shape, and has a recess recessed toward the third side wall 10c in plan view. The second inner edge portion 11b has second attachment parts to which second attachment portions described below are attached. For example, two third holes 13b1 are formed as the second attachment parts. The third holes 13b1 are formed, for example, on the third side wall 10c side of the second inner edge portion 11b. The third holes 13b1 are recessed (or penetrate) from the upper surface toward the lower surface of the second inner edge portion 11b. The positions and the number of the third holes 13b1 are merely examples, and the present embodiment is not limited thereto.

The first beam portion 11c is integrally provided between the fourth side wall 10d side of the first side wall 10a and the fourth side wall 10d side of the second side wall 10b. The first beam portion 11c may have a linear rod shape in plan view. The rod shape may be a cylindrical shape or a columnar shape. The first beam portion 11c may have a flat plate shape.

The second beam portion 11d is integrally provided between the third side wall 10c side of the first side wall 10a and the third side wall 10c side of the second side wall 10b. The second beam portion 11d may have a linear rod shape in plan view. The rod shape may be a cylindrical shape or a columnar shape. The second beam portion 11d may have a flat plate shape.

The opening 12 is partitioned into a first opening portion 12a, a second opening portion 12b, and a third opening portion 12c by the first beam portion 11c and the second beam portion 11d. The first opening portion 12a is the region surrounded by the first inner edge portion 11a and the first beam portion 11c. The second opening portion 12b is the region surrounded by the first beam portion 11c, the second beam portion 11d, the first side wall 10a, and the second side wall 10b. The third opening portion 12c is the region surrounded by the second inner edge portion 11b, the first side wall 10a, the second side wall 10b, and the second beam portion 11d. In addition, the first opening portion 12a, the second opening portion 12b, and the third opening portion 12c are provided in order from the fourth side wall 10d toward the third side wall 10c along the first side wall 10a and the second side wall 10b.

The first opening portion 12a may be located to face the insulating circuit board 3f. The third opening portion 12c may be located to face the insulating circuit board 3e. In addition, it is preferable that the first opening portion 12a and the third opening portion 12c have a shape such that the insulating circuit board 3f and the insulating circuit board 3e are entirely visible, respectively, in plan view. For example, the first opening portion 12a and the third opening portion 12c may have a rectangular shape.

The second opening portion 12b may be located to face the insulating circuit board 3a, the insulating circuit board 3b, the insulating circuit board 3c, and the insulating circuit board 3d. In addition, it is preferable that the second opening portion 12b have a shape such that the insulating circuit board 3a, the insulating circuit board 3b, the insulating circuit board 3c, and the insulating circuit board 3d are entirely visible in plan view. For example, the second opening portion 12b may have a rectangular shape. In FIG. 6, a part of the insulating circuit board 3a and a part of the insulating circuit board 3b overlap the second beam portion 11d. In FIG. 6, a part of the insulating circuit board 3c and a part of the insulating circuit board 3d overlap the first beam portion 11c.

The first positioning member 14a is integrally formed with the inner side of the first side wall 10a. The upper surface of the first positioning member 14a includes a first positioning area 14a1 and a first locking member 14a2. The first positioning area 14a1 is an area lower than the upper surface of the first positioning member 14a and has a terrace shape. The first positioning area 14a1 and the upper surface of the first positioning member 14a form a step.

The first locking member 14a2 is integrally formed on the second beam portion 11d (third side wall 10c) side of the first positioning area 14a1. The first locking member 14a2 locks the movement of the second nut housing portion 30 as described below. That is, the first locking member 14a2 is formed on a portion of the first positioning area 14a1, the portion being located in the movement (guiding) direction of the second nut housing portion 30. Thus, the first locking member 14a2 is a protrusion formed on the first positioning area 14a1. The shape of the protrusion may be, for example, a columnar shape or a hemispherical shape. Examples of the columnar shape include a cylindrical shape and a prismatic shape. The size of the protrusion may be any size as long as the protrusion is formed in the first positioning area 14a1.

The second positioning member 14b faces the first positioning member 14a, and is integrally formed with the inner side of the second side wall 10b. The second positioning member 14b has the same configuration as the first positioning member 14a. That is, the second positioning member 14b also includes a second positioning area 14b1 and a second locking member 14b2 on the upper surface of the second positioning member 14b. The second positioning area 14b1 is similar to the first positioning area 14a1, and the second locking member 14b2 is similar to the first locking member 14a2.

The length (parallel to the width direction of the case 10) between the step of the first positioning area 14a1 of the first positioning member 14a and the step of the second positioning area 14b1 of the second positioning member 14b is substantially equal to the length of a second nut housing portion 30 described below in the same direction.

The case 10 may be formed of a thermoplastic resin. Examples of the resin include polyphenylene sulfide (PPS) resin.

In addition, the case 10 integrally includes a first sense terminal 15a1, a second sense terminal 15a2, and a third sense terminal 15b. Furthermore, the case 10 integrally includes first control terminals 15c and second control terminals 15d. The first sense terminal 15a1, the second sense terminal 15a2, the third sense terminal 15b, the first control terminals 15c, and the second control terminals 15d may be formed of the above-described metal having excellent conductivity as a main component, and may be subjected to the above-described plating treatment.

The first sense terminal 15a1 is included in the first side wall 10a. An outer end portion (not illustrated) of the first sense terminal 15a1 is exposed upward from the first side wall 10a. For example, the outer end portion of the first sense terminal 15a1 may be covered with the same material as that of the case 10, and may be integrally bonded to the upper portion of the inner side of the first side wall 10a. The outer end portion covered in this manner may be provided between the first inner edge portion 11a of the first side wall 10a and the first positioning member 14a. An inner end portion of the first sense terminal 15a1 extends from the inner surface of the first side wall 10a toward the second side wall 10b, and extends downward as it extends toward the fourth side wall 10d partway.

The second sense terminal 15a2 is included in the first side wall 10a and the first positioning member 14a. An outer end portion (not illustrated) of the second sense terminal 15a2 is exposed upward from the first side wall 10a. Similarly to the first sense terminal 15a1, the outer end portion of the second sense terminal 15a2 may be covered with the same material as that of the case 10, and may be integrally bonded to the upper portion of the inner side of the first side wall 10a. The outer end portion covered in this manner may be provided between the first inner edge portion 11a of the first side wall 10a and the first positioning member 14a. An inner end portion of the second sense terminal 15a2 extends from the first positioning member 14a toward the fourth side wall 10d and extends as it extends downward partway. The third sense terminal 15b is included in the second side wall 10b. An outer end portion (not illustrated) of the third sense terminal 15b is exposed upward from the second side wall 10b. Similarly to the first sense terminal 15a1, the outer end portion of the third sense terminal 15b may be covered with the same material as that of the case 10, and may be integrally bonded to the upper portion of the inner side of the second side wall 10b. The outer end portion covered in this manner may be provided between the first inner edge portion 11a of the second side wall 10b and the second positioning member 14b. An inner end portion of the third sense terminal 15b extends from the second side wall 10b toward the first side wall 10a, and extends downward as it extends toward the third side wall 10c partway.

The first control terminals 15c are included in the first side wall 10a and the first beam portion 11c. An outer end portion (not illustrated) of the first control terminals 15c is exposed upward from the first side wall 10a. Similarly to the first sense terminal 15a1, the outer end portion of the first control terminals 15c may be covered with the same material as that of the case 10, and may be integrally bonded to the upper portion of the inner side of the first side wall 10a. The outer end portion covered in this manner may be provided between the first inner edge portion 11a of the first side wall 10a and the first positioning member 14a. An inner end portion of the first control terminals 15c extends from the first beam portion 11c toward the fourth side wall 10d and extends downward partway.

The second control terminals 15d are included in the second side wall 10b and the second beam portion 11d. An outer end portion (not illustrated) of the second control terminals 15d is exposed upward from the second side wall 10b. Similarly to the first sense terminal 15a1, the outer end portion of the second control terminals 15d may be covered with the same material as that of the case 10, and may be integrally bonded to the upper portion of the inner side of the second side wall 10b. The outer end portion covered in this manner may be provided between the second inner edge portion 11b of the second side wall 10b and the second positioning member 14b. An inner end portion of the second control terminals 15d extends from the second beam portion 11d toward the third side wall 10c, and extends downward partway.

Next, a control terminal bonding step of bonding various terminals included in the case 10 is performed (step P4). Various terminals included in the case 10 disposed on the heat dissipation base 2 in step P3 are bonded to the insulating circuit boards 3a, 3c, 3d, 3e, and 3f. Examples of the bonding here include bonding with a metal sintered material, ultrasonic bonding, and laser welding bonding. In the present embodiment, ultrasonic bonding is performed.

The first sense terminal 15a1 of the case 10 is pressed against the conductive circuit pattern 6c2 of the insulating circuit board 3c by a tool that passes through the second opening portion 12b, and is bonded by ultrasonic vibration. The second sense terminal 15a2 of the case 10 is bonded to the conductive circuit pattern 6a1 of the insulating circuit board 3a in the same way. The third sense terminal 15b of the case 10 is bonded to the conductive circuit pattern 6d2 of the insulating circuit board 3d.

The first control terminals 15c of the case 10 are bonded to the conductive circuit pattern 6f of the insulating circuit board 3f by ultrasonic bonding. The tool for performing this ultrasonic bonding presses the first control terminals 15c against the insulating circuit board 3f through the first opening portion 12a. The first control terminals 15c may be bonded to the conductive circuit pattern 6f of the insulating circuit board 3f by laser welding or by a metal sintered material. Also in these cases, the tool used for welding and bonding passes through the first opening portion 12a and bonds the first control terminals 15c. Similarly, the second control terminals 15d are bonded to the conductive circuit pattern 6e of the insulating circuit board 3e through the third opening portion 12c by a tool used for bonding.

In this manner, the first opening portion 12a is provided on the insulating circuit board 3f. A tool for bonding enters from the first opening portion 12a, and the first control terminals 15c are bonded to the insulating circuit board 3f. After such bonding is completed, the first nut housing portion 20 is provided in the first opening portion 12a as described below. Therefore, the first nut housing portion 20 does not hinder the bonding of the first control terminals 15c to the insulating circuit board 3f. Similarly, when the second opening portion 12b is provided on the insulating circuit board 3e, the third nut housing portion 40 does not hinder the bonding of the second control terminals 15d to the insulating circuit board 3e.

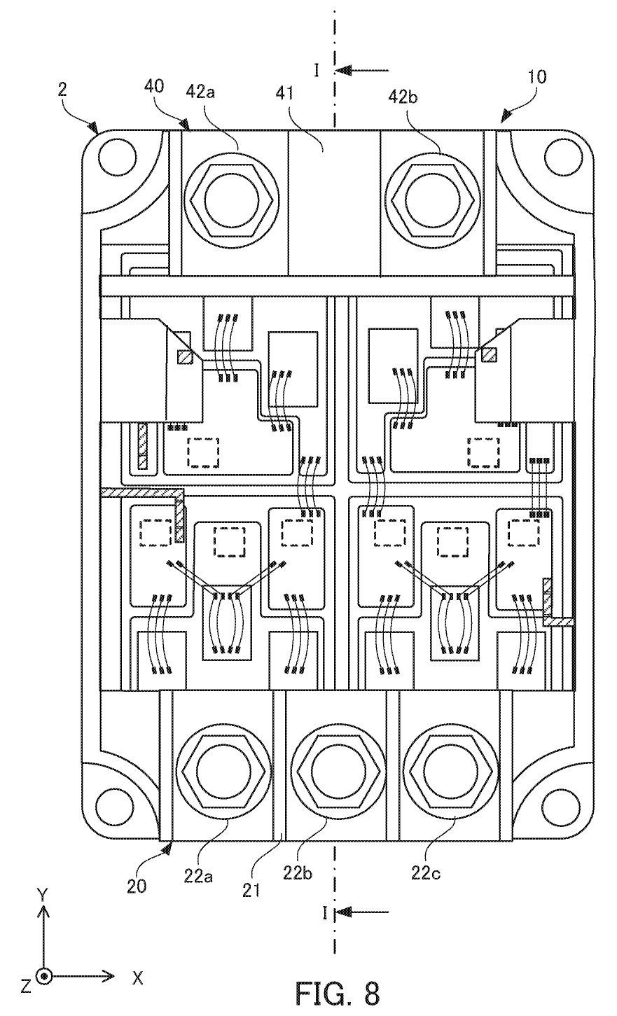

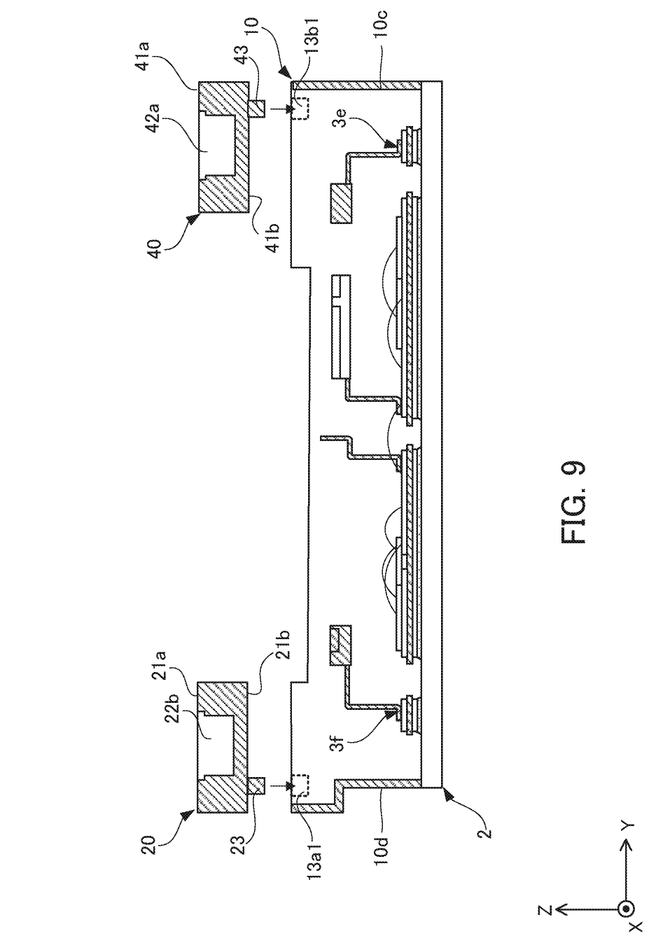

Next, a nut housing portion attachment (vertical direction) step of attaching the first nut housing portion 20 and the third nut housing portion 40 to the case 10 is performed (step P5). The nut housing portion attachment (vertical direction) step will be described with reference to FIGS. 8 and 9. FIG. 8 is a plan view illustrating a nut housing portion attachment (vertical direction) step included in the method of manufacturing the semiconductor device according to the first embodiment. FIG. 9 is a cross-sectional view illustrating a nut housing portion attachment (vertical direction) step included in the method of manufacturing the semiconductor device according to the first embodiment. FIG. 9 is a cross-sectional view taken along a dashed-dotted line I-I in FIG. 8.

The first nut housing portion 20 has a rectangular prism shape. The first nut housing portion 20 includes an upper surface 21a (first housing upper surface) and a lower surface 21b (first housing lower surface). The first nut housing portion 20 further includes side surfaces (reference numerals omitted) surrounding the four sides of the upper surface 21a and the lower surface 21b.

The upper surface 21a and the lower surface 21b have the same shape and the same size. The shape is, for example, a rectangular shape in plan view. Both short sides of the upper surface 21a and the lower surface 21b are parallel to the first side wall 10a and the second side wall 10b (the longitudinal direction of the case 10). Both long sides of the upper surface 21a and the lower surface 21b are parallel to the third side wall 10c and the fourth side wall 10d (the width direction of the case 10).

Housing regions 22a, 22b, and 22c are formed in the upper surface 21a. The housing regions 22a, 22b, and 22c are recessed from the upper surface 21a. The first nuts are housed in the housing regions 22a, 22b, and 22c. The housing regions 22a, 22b, and 22c may have a size and a depth capable of housing first nuts.

The lower surface 21b has first attachment portions for attachment to the case 10. For example, the first attachment portions are first protrusions 23 (see FIG. 9). Here, the two first protrusions 23 are integrally formed on the fourth side wall 10d side of the lower surface 21b in plan view. When the first nut housing portion 20 is attached to the case 10 in the vertical direction to cover the first opening portion 12a, the first protrusions 23 are fitted into the two first holes 13a1. The first protrusions 23 may have a shape and a size that is fitted into the first holes 13a. When the first nut housing portion 20 is attached to the case 10, an adhesive may be applied to either the first holes 13a1 or the first protrusions 23. The first nut housing portion 20 to which the adhesive has been applied is attached perpendicularly to the first opening portion 12a of the case 10. The first nut housing portion 20 attached to the case 10 faces the insulating circuit board 3f via the first opening portion 12a.

The third nut housing portion 40 may also have the same shape as the first nut housing portion 20. The third nut housing portion 40 includes an upper surface 41a (third housing upper surface) and a lower surface 41b (third housing lower surface). The third nut housing portion 40 further includes side surfaces (reference numerals omitted) surrounding the four sides of the upper surface 41a and the lower surface 41b. Two housing regions 42a and 42b in which third nuts are housed are formed in the upper surface 41a of the third nut housing portion 40. Similarly to the first nut housing portion 20, two third protrusions 43 are integrally formed on the lower surface 41b as an example of the third attachment portions (corresponding to the two third holes in FIG. 6).

When the third nut housing portion 40 is attached to the case 10 in the vertical direction to cover the third opening portions 12c, the third protrusions 43 are fitted into the third holes 13b1. An adhesive may be applied to either the third holes 13b1 or the third protrusions 43. The third nut housing portion 40 to which the adhesive has been applied is attached perpendicularly to the third opening portion 12c of the case 10. The third nut housing portion 40 attached to the case 10 faces the insulating circuit board 3e via the third opening portion 12c.

The first nuts are housed in the housing regions 22a, 22b, and 22c of the first nut housing portion 20 attached to the case 10 in this manner. Similarly, the third nuts are housed in the housing regions 42a and 42b of the third nut housing portion 40. The first nut housing portion 20 and the third nut housing portion 40 may also be formed of a thermoplastic resin, similarly to the case 10.

In this way, the first nut housing portion 20 is moved down vertically (in the thickness direction of the case 10) with respect to the case 10, and the first protrusions 23 are fitted into the first holes 13a1. As a result, the first nut housing portion 20 is attached to the case 10 as it faces the insulating circuit board 3f and covers the first opening portion 12a. That is, the first nut housing portion 20 hardly comes into contact with other components of the case 10 when attached to the case 10. Therefore, the adhesive applied to the first nut housing portion 20 hardly contaminates the surroundings. The same applies to the third nut housing portion 40. Therefore, since the first nut housing portion 20 and the third nut housing portion 40 may be easily attached to the case 10, the assemblability of the semiconductor device 1 is improved.

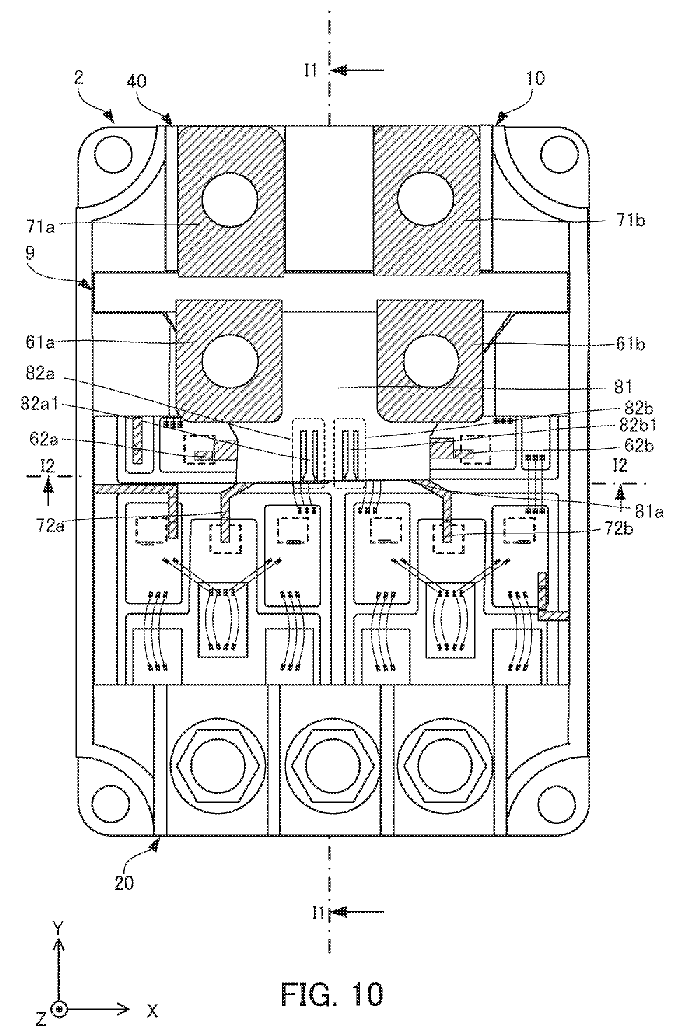

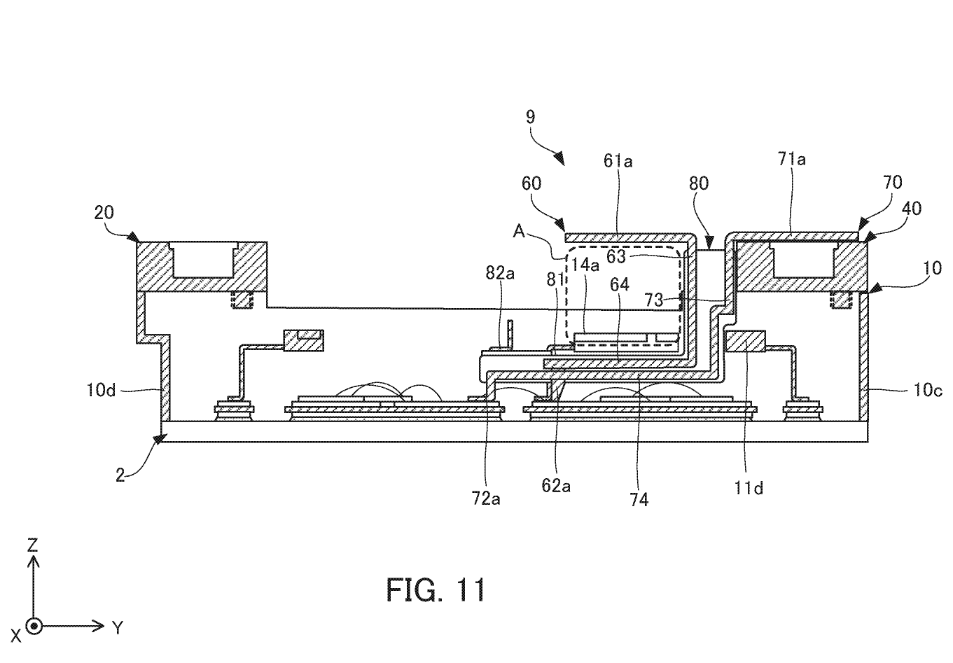

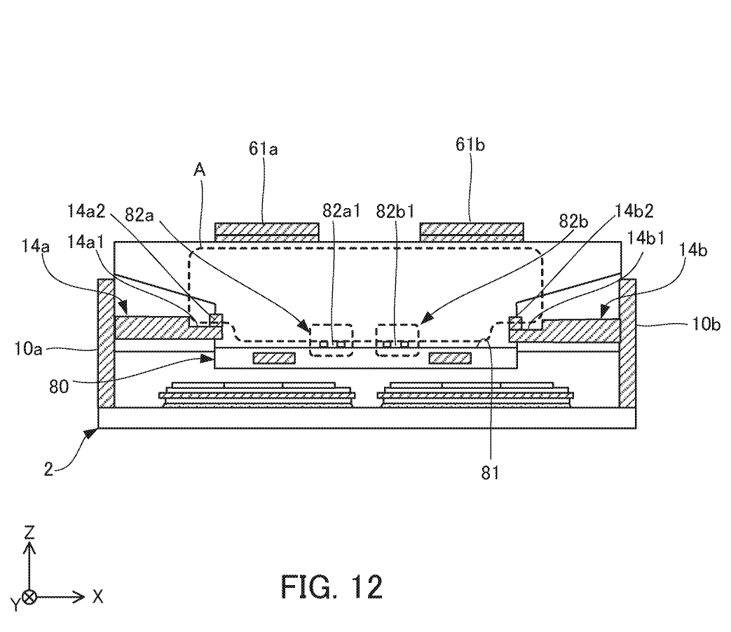

Next, a terminal unit attachment step of attaching a terminal unit 9 is performed (step P6). The terminal unit attachment step will be described with reference to FIGS. 10-12. FIG. 10 is a plan view illustrating a terminal unit attachment step included in the method of manufacturing the semiconductor device according to the first embodiment. FIG. 11 is a first cross-sectional view illustrating the terminal unit attachment step included in the method of manufacturing the semiconductor device according to the first embodiment. FIG. 12 is a second cross-sectional view illustrating the terminal unit attachment step included in the method of manufacturing the semiconductor device according to the first embodiment. FIG. 11 is a cross section taken along a dashed-dotted line I1-I1 in FIG. 10. FIG. 12 is a cross section taken along a dashed-dotted line I2-I2 in FIG. 10.

The terminal unit 9 includes the second external connection terminal 60, the third external connection terminal 70, and a sealing member 80. The terminal unit 9 is attached between the first side wall 10a and the second side wall 10b of the case 10. At this time, the second external connection terminal 60 is disposed on the insulating circuit board 3a and the insulating circuit board 3b. The third external connection terminal 70 is disposed on the upper surface 41a of the third nut housing portion 40, the insulating circuit board 3c, and the insulating circuit board 3d. The second external connection terminal 60 and the third external connection terminal 70 may be made of a metal having excellent conductivity. This metal is, for example, silver, copper, nickel, or an alloy containing at least one of these metals. In order to improve corrosion resistance, the surfaces of the second external connection terminal 60 and the third external connection terminal 70 may be plated. The plating material is the same as that described above.

The sealing member 80 of the terminal unit 9 is made of the same material as the case 10. The terminal unit 9 is integrally formed by using, the second external connection terminal 60 and the third external connection terminal 70 made of such a material.

The second external connection terminal 60 (external connection terminal) integrally includes second external connection portions 61a and 61b (external connection portions), leg portions 62a and 62b, a vertical wiring portion 63, and a horizontal wiring portion 64. When the terminal unit 9 is attached to the case 10, the second external connection portions 61a and 61b face the heat dissipation base 2.

When the terminal unit 9 is attached to the case 10, the leg portion 62a is disposed on the conductive circuit pattern 6a2 of the insulating circuit board 3a, and the leg portion 62b is disposed on the conductive circuit pattern 6b2 of the insulating circuit board 3b. Thereafter, the leg portion 62a is bonded to the conductive circuit pattern 6a2, and the leg portion 62b is bonded to the conductive circuit pattern 6b2. Examples of the bonding include bonding by a metal sintered material, which is the bonding member described above, ultrasonic bonding, and bonding by laser welding.

Each of the second external connection portions 61a and 61b is connected to one end (upper end) of the vertical wiring portion 63. The vertical wiring portion 63 extends perpendicularly to the heat dissipation base 2 from the second external connection portions 61a and 61b. The horizontal wiring portion 64 is bonded to the other end (lower end) of the vertical wiring portion 63. The horizontal wiring portion 64 extends parallel to the heat dissipation base 2 from the vertical wiring portion 63 toward the fourth side wall 10d. The leg portion 62a and the leg portion 62b are respectively connected to both sides of the horizontal wiring portion 64, the sides facing the first side wall 10a and the second side wall 10b.

The third external connection terminal 70 integrally includes third external connection portions 71a and 71b, leg portions 72a and 72b, a vertical wiring portion 73, and a horizontal wiring portion 74. When the terminal unit 9 is attached to the case 10, the third external connection portions 71a and 71b are disposed on the upper surface 41a of the third nut housing portion 40.

When the terminal unit 9 is attached to the case 10, the leg portion 72a is disposed on the conductive circuit pattern 6c1 of the insulating circuit board 3c, and the leg portion 72b is disposed on the conductive circuit pattern 6d1 of the insulating circuit board 3d. Thereafter, the leg portion 72a is bonded to the conductive circuit pattern 6c1, and the leg portion 72b is bonded to the conductive circuit pattern 6d1. As described above, examples of the bonding include bonding by a metal sintered material, which is the above-described bonding member, ultrasonic bonding, and bonding by laser welding.

The third external connection portions 71a and 71b are connected to one end (upper end) of the vertical wiring portion 73. The vertical wiring portion 73 extends perpendicularly to the heat dissipation base 2 from the third external connection portions 71a and 71b. The vertical wiring portion 73 extends downward while avoiding the second beam portion 11d on the way toward the heat dissipation base 2. The vertical wiring portion 73 faces the vertical wiring portion 63 of the second external connection terminal 60.

The horizontal wiring portion 74 is connected to the other end (lower end) of the vertical wiring portion 73. The horizontal wiring portion 74 extends parallel to the heat dissipation base 2 from the vertical wiring portion 73 toward the fourth side wall 10d. The horizontal wiring portion 74 extends between the horizontal wiring portion 64 of the second external connection terminal 60 and the heat dissipation base 2. The leg portions 72a and 72b are respectively connected to end portions of the horizontal wiring portion 74, the end portions facing the fourth side wall 10d.

The sealing member 80 seals the vertical wiring portion 63 and the horizontal wiring portion 64 of the second external connection terminal 60 and the vertical wiring portion 73 and the horizontal wiring portion 74 of the third external connection terminal 70. The leg portions 62a and 62b of the second external connection terminal 60 are exposed from the sealing member 80. The leg portions 72a and 72b of the third external connection terminal 70 are exposed from the sealing member 80.

The sealing member 80 includes a horizontal sealing surface 81 and regulating members 82a and 82b. The horizontal sealing surface 81 is an upper surface of a portion of the sealing member 80, the portion sealing the horizontal wiring portion 64 of the second external connection terminal 60 and the horizontal wiring portion 74 of the third external connection terminal 70.

When the terminal unit 9 is attached to the case 10, the horizontal sealing surface 81 may be substantially parallel to the upper surface 2a of the heat dissipation base 2. The regulating members 82a and 82b are integrally formed on the horizontal sealing surface 81. The regulating member 82a includes a gap 82a1. The gap 82a1 is parallel to the first side wall 10a and the second side wall 10b. The regulating member 82a may be, for example, a flat plate-shaped member having the gap 82a1 formed in the upper surface thereof. Alternatively, the regulating member 82a may be two rails provided with the gap 82a1 therebetween. Similarly to the regulating member 82a, the regulating member 82b may have a gap 82b1 parallel to the first side wall 10a and the second side wall 10b.

When the terminal unit 9 is attached to the case 10 in this manner, an attachment region to which the second nut housing portion 30 is attached is formed. The attachment region corresponds to a region A indicated by a broken line in FIGS. 11 and 12. The height of the region A is the height (gap) from the horizontal sealing surface 81 of the sealing member 80 to the second external connection portions 61a and 61b of the second external connection terminal 60. The horizontal length of the region A (in the width direction of the case 10) is the distance between the step of the first positioning member 14a and the step of the second positioning member 14b.

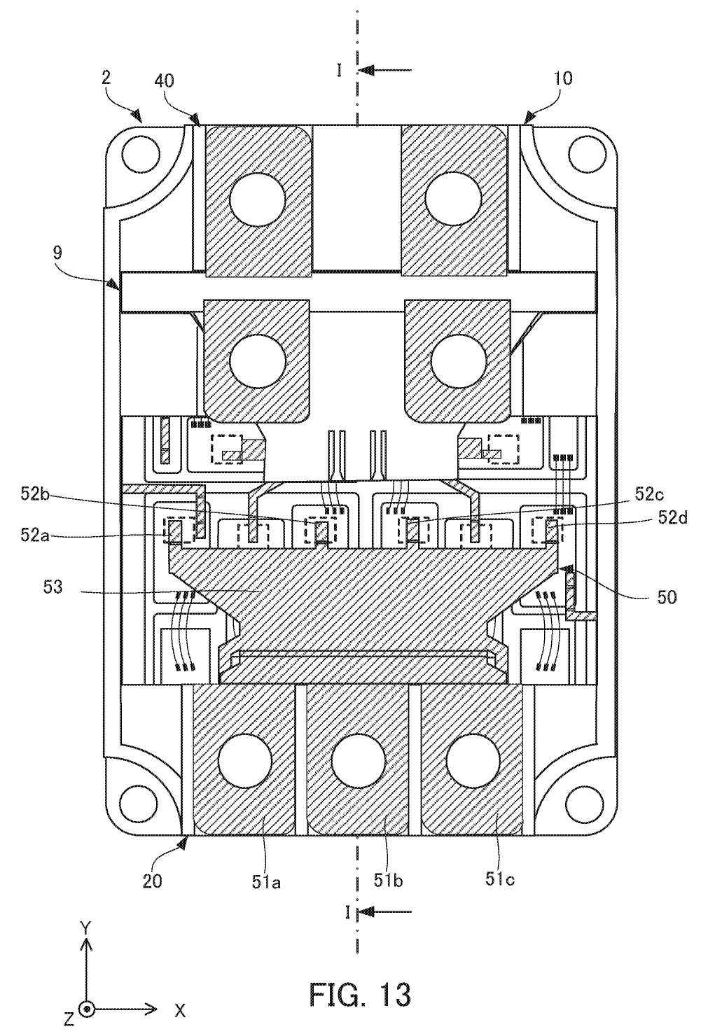

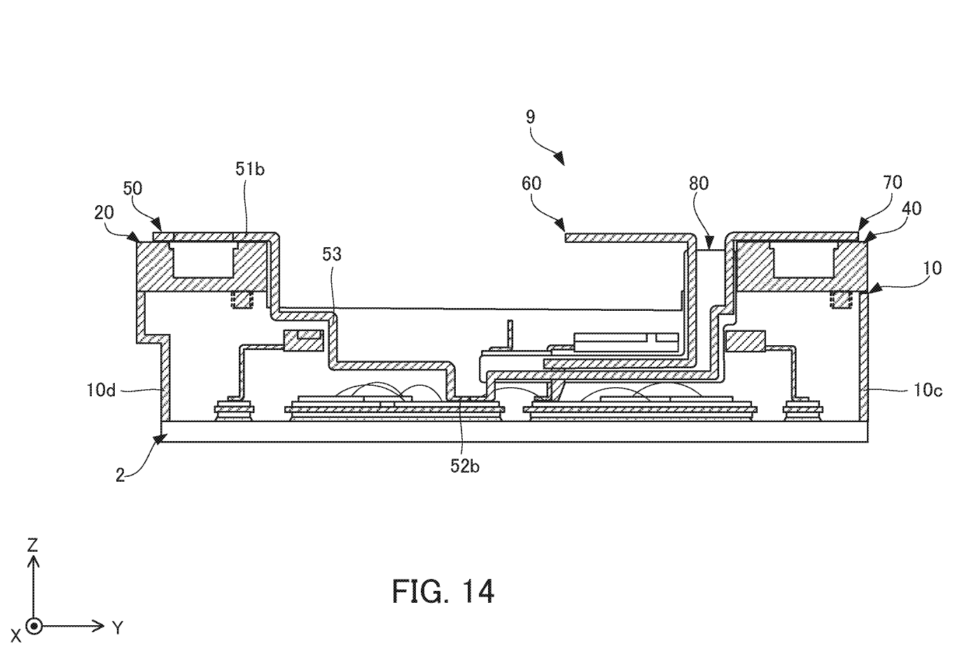

Next, a main terminal attachment step of attaching the first external connection terminal 50 to the first nut housing portion 20 is performed (step P7). The main terminal attachment step will be described with reference to FIGS. 13 and 14. FIG. 13 is a plan view illustrating a main terminal attachment step included in the method of manufacturing the semiconductor device according to the first embodiment. FIG. 14 is a cross-sectional view illustrating the main terminal attachment step included in the method of manufacturing the semiconductor device according to the first embodiment. FIG. 14 is a cross-sectional view taken along a dashed-dotted line I-I in FIG. 13.

The first external connection terminal 50 is disposed on the upper surface 21a of the first nut housing portion 20, the insulating circuit board 3c, the insulating circuit board 3d, and the insulating circuit board 3f. The first external connection terminal 50 is made of a metal having excellent conductivity, and a surface thereof may be plated, as in the case with the second external connection terminal 60 and the third external connection terminal 70.

The first external connection terminal 50 integrally includes first external connection portions 51a, 51b, and 51c, leg portions 52a and 52b, leg portions 52c and 52d, and a wiring portion 53. The first external connection portions 51a, 51b, and 51c are disposed to correspond to the housing regions 22a, 22b, and 22c of the upper surface 21a of the first nut housing portion 20.

The leg portions 52a and 52b are bonded to the conductive circuit patterns 6c2 and 6c3 of the insulating circuit board 3c, respectively. The leg portions 52c and 52d are bonded to the conductive circuit patterns 6d3 and 6d2 of the insulating circuit board 3c, respectively. Examples of the bonding include bonding by a metal sintered material, which is the bonding member described above, ultrasonic bonding, and bonding by laser welding.

The first external connection portions 51a, 51b, and 51c are connected to one end portion of the wiring portion 53. The leg portions 52a and 52b and the leg portions 52c and 52d are connected to the other end portion of the wiring portion 53. The wiring portion 53 electrically connects the first external connection portions 51a, 51b, and 51c, the leg portions 52a and 52b, and the leg portions 52c and 52d. The wiring portion 53 extends from the first external connection portions 51a, 51b, and 51c to the heat dissipation base 2 side along the side surface (on the third side wall 10c side) of the first nut housing portion 20. The wiring portion 53 extends to the heat dissipation base 2 side along the upper surface of the first beam portion 11c and the side surface (on the third side wall 10c side) of the first beam portion 11c.

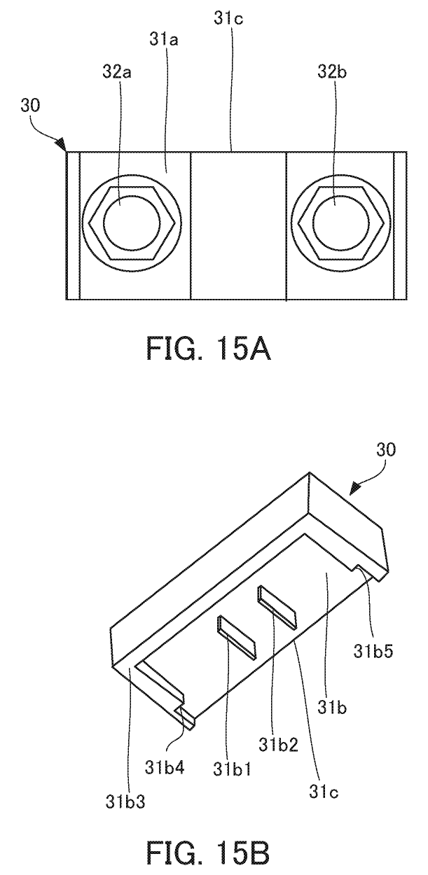

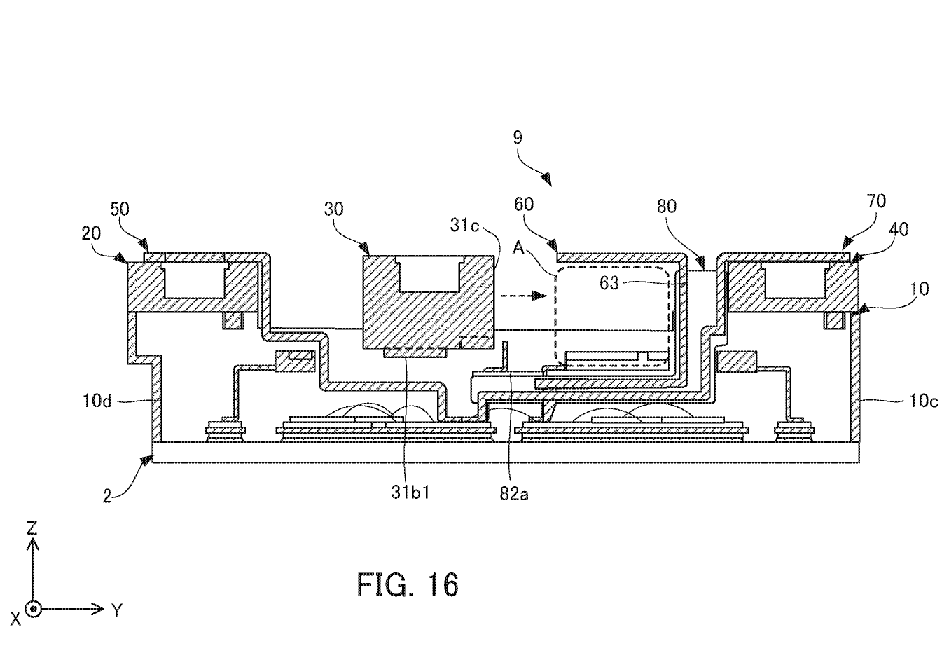

Next, a nut housing portion attachment (horizontal direction) step of attaching the second nut housing portion 30 is performed (step P8). The nut housing portion attachment (horizontal direction) step will be described with reference to FIGS. 15-18. FIGS. 15A and 15B are diagrams illustrating the second nut housing portion included in the semiconductor device according to the first embodiment. FIGS. 16 to 18 are cross-sectional views illustrating the nut housing portion attachment (horizontal direction) step included in the method of manufacturing the semiconductor device according to the first embodiment. FIG. 15A is a plan view of the second nut housing portion 30, and FIG. 15B is a perspective view of the rear surface of the second nut housing portion 30. The cross sections in FIGS. 16-18 are the same as those in FIGS. 11 and 14.

In the nut housing portion attachment (horizontal direction) step, the second nut housing portion 30 is attached to the terminal unit 9 in the case 10. As illustrated in FIGS. 15A and 15B, the second nut housing portion 30 has a rectangular prism shape. The second nut housing portion 30 includes an upper surface 31a (second housing upper surface) and a lower surface 31b (second housing lower surface). The second nut housing portion 30 also has side surfaces (reference numerals omitted) surrounding the four sides of the upper surface 31a and the lower surface 31b. One of the side surfaces is an opposing surface 31c.

The upper surface 31a and the lower surface 31b have rectangular shapes of the same shape and the same size. The shape is, for example, a rectangular shape in plan view. Both short sides of the upper surface 31a and the lower surface 31b are parallel to the first side wall 10a and the second side wall 10b (the longitudinal direction of the case 10). Both long sides of the upper surface 31a and the lower surface 31b are parallel to the third side wall 10c and the fourth side wall 10d (the width direction of the case 10).

The upper surface 31a has housing regions 32a and 32b. The housing regions 32a and 32b are recessed from the upper surface 31a. The housing regions 32a and 32b house second nuts. The housing regions 32a and 32b may have a size and a depth capable of housing the second nuts.

Projections 31b1 and 31b2 and a frame portion 31b3 are formed on the lower surface 31b. The protrusions 31b1 and 31b2 each form a continuous straight line in plan view. The protrusions 31b1 and 31b2 may each have, for example, a flat plate shape parallel to both short sides of the second nut housing portion 30. The thickness of the protrusions 31b1 and 31b2 (in the longitudinal direction of the second nut housing portion 30) is set such that the protrusions 31b1 and 31b2 are allowed to enter the gaps 82a1 and 82b1 of the regulating members 82a and 82b.

The frame portion 31b3 is formed around the outer edge corresponding to three side surfaces of the lower surface 31b, specifically, the three side surfaces other than the opposing surface 31c. The frame portion 31b3 protrudes downward from the lower surface 31b. The protrusions 31b1 and 31b2 may extend downward further than the frame portion 31b3. The frame portion 31b3 includes contact surfaces 31b4 and 31b5 facing in the direction of the opposing surface 31c. The frame portion 31b3 has the contact surfaces 31b4 and 31b5 such that the contact surfaces 31b4 and 31b5 are displaced (retreated) from the opposing surface 31c. The contact surfaces 31b4 and 31b5 face in the same direction as the opposing surface 31c.

When the second nut housing portion 30 is attached to the terminal unit 9 in the case 10, an adhesive is applied to both short sides of the frame portion 31b3 of the second nut housing portion 30. Then, the second nut housing portion 30 is disposed between the first external connection terminal 50 and the second external connection terminal 60. At this time, the opposing surface 31c of the second nut housing portion 30 faces the third side wall 10c (FIG. 16).

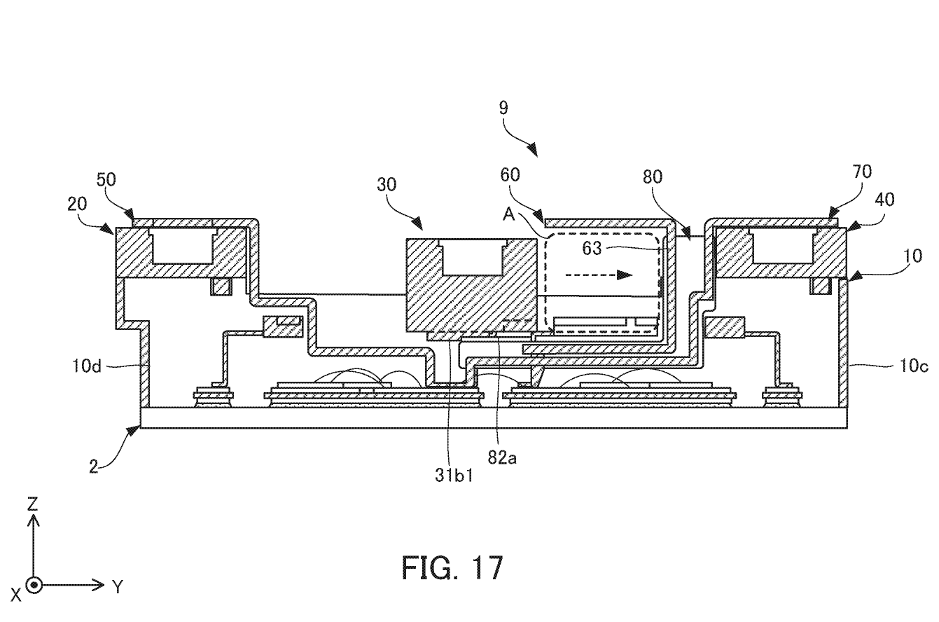

The second nut housing portion 30 starts to move toward the vertical wiring portion 63 of the second external connection terminal 60 included in the terminal unit 9, and further, parallel to the horizontal sealing surface 81 of the terminal unit 9. The protrusion 31b1 and the protrusion 31b2 of the lower surface 31b of the second nut housing portion 30, which moves horizontally toward the vertical wiring portion 63 of the second external connection terminal 60, pass through the gap 82a1 and the gap 82b1 of the horizontal sealing surface 81, respectively. Accordingly, the second nut housing portion 30 is stably and reliably guided toward the attachment region (region A) of the terminal unit 9 in the case 10 (FIG. 17).

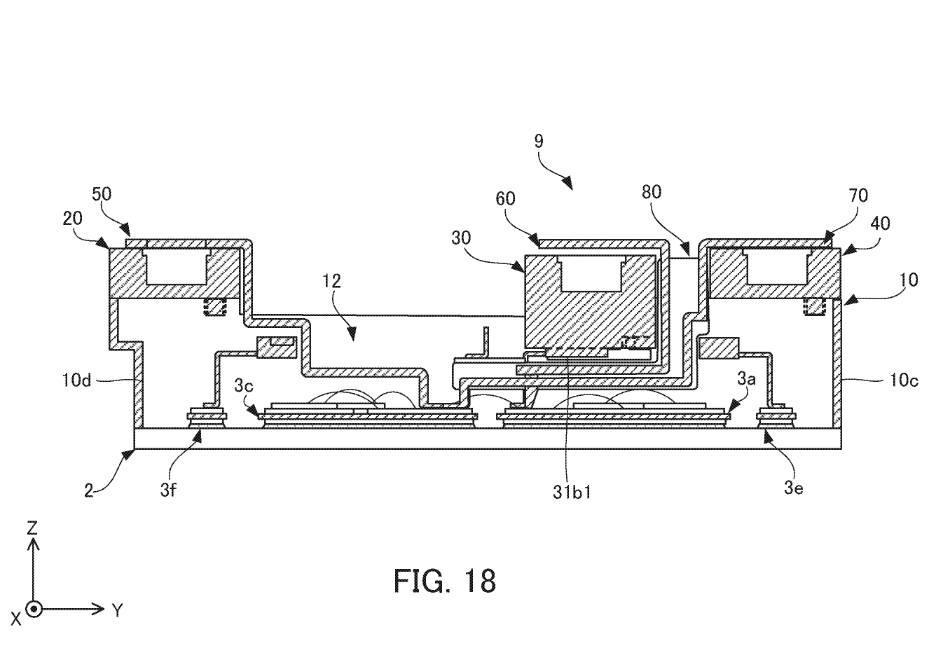

Both short sides of the frame portion 31b3 of the lower surface 31b of the second nut housing portion 30 guided in this manner slide on the first positioning area 14a1 of the first positioning member 14a and the second positioning area 14b1 of the second positioning member 14b. Then, the contact surface 31b4 and the contact surface 31b5 of the frame portion 31b3 of the second nut housing portion 30 come into contact with the first locking member 14a2 of the first positioning member 14a and the second locking member 14b2 of the second positioning member 14b (FIG. 18).

In this way, the second nut housing portion 30 is guided toward the attachment region (region A) by the protrusions 31b1 and 31b2 passing through the regulating members 82a and 82b. Therefore, the second nut housing portion 30 is smoothly attached to the attachment region without coming into contact with the inside of the case 10 and the terminal unit 9 while moving toward the attachment region. In addition, since the second nut housing portion 30 does not come into contact with the inside of the case 10 and the terminal unit 9, adhesion of the adhesive to the inside of the case 10 and the terminal unit 9 is prevented.

Outer end portions of the first sense terminal 15a1, the second sense terminal 15a2, the third sense terminal 15b, the first control terminals 15c (wiring members), and the second control terminals 15d are covered and integrally provided with the first side wall 10a and the second side wall 10b of the case 10. Therefore, the first side wall 10a and the second side wall 10b of the case 10 are not provided with a member for guiding the second nut housing portion 30 to the attachment region. Even if such a member is provided, there is a possibility that these outer end portions interfere with the guide of the second nut housing portion 30. Therefore, the regulating members 82a and 82b for guiding the second nut housing portion 30 to the attachment region are provided on the horizontal sealing surface 81 of the terminal unit 9. As described above, the second nut housing portion 30 is accurately attached to the attachment region (region A) of the terminal unit 9 in the case 10, and the assemblability of the second nut housing portion 30 is improved.

Next, a sealing step of sealing the inside of the case 10 is performed (step P9). The case 10 is filled with a sealing member (not illustrated). The sealing member seals all the insulating circuit boards, all the semiconductor chips, and the bonding wires on the heat dissipation base 2. The height (thickness) of the sealing member from the upper surface 2a of the heat dissipation base 2 may be any height as long as the sealing member is able to seal all the insulating circuit boards, all the semiconductor chips, and the bonding wires on the heat dissipation base 2. The sealing member is an insulating polymer gel. The sealing member may preferably contain a silicone gel as a main component.

Thus, the semiconductor device 1 illustrated in FIGS. 1 and 2 is obtained. A lid portion may be attached between the first nut housing portion 20 and the second nut housing portion 30 of the semiconductor device 1.

The semiconductor device 1 includes the insulating circuit board 3f, the insulating circuit boards 3a, 3b, 3c, and 3d, and the case 10 which includes side walls that surround the opening 12 in plan view and that include the first side wall 10a and the second side wall 10b extending in the longitudinal direction, and which houses the insulating circuit board 3f and the insulating circuit boards 3a, 3b, 3c, and 3d sequentially disposed in the longitudinal direction. The semiconductor device 1 also includes the second external connection terminal 61 having a lower end electrically connected to the insulating circuit boards 3c and 3d and having, at an upper end thereof, the second external connection portions 61a and 61b facing the insulating circuit boards 3a and 3b and extending in a direction opposite to the longitudinal direction. The semiconductor device 1 further includes the first nut housing portion 20 and the second nut housing portion 30. The first nut housing portion 20 is guided in the thickness direction of the case 10, covers the opening 12, is attached to the first side wall 10a and the second side wall 10b, and faces the insulating circuit board 3f. The second nut housing portion 30 is guided in the longitudinal direction between the first side wall 10a and the second side wall 10b and is provided on the insulating circuit boards 3a and 3b side of the second external connection portions 61a and 61b. This improves the assemblability of the semiconductor device 1.

### Second Embodiment

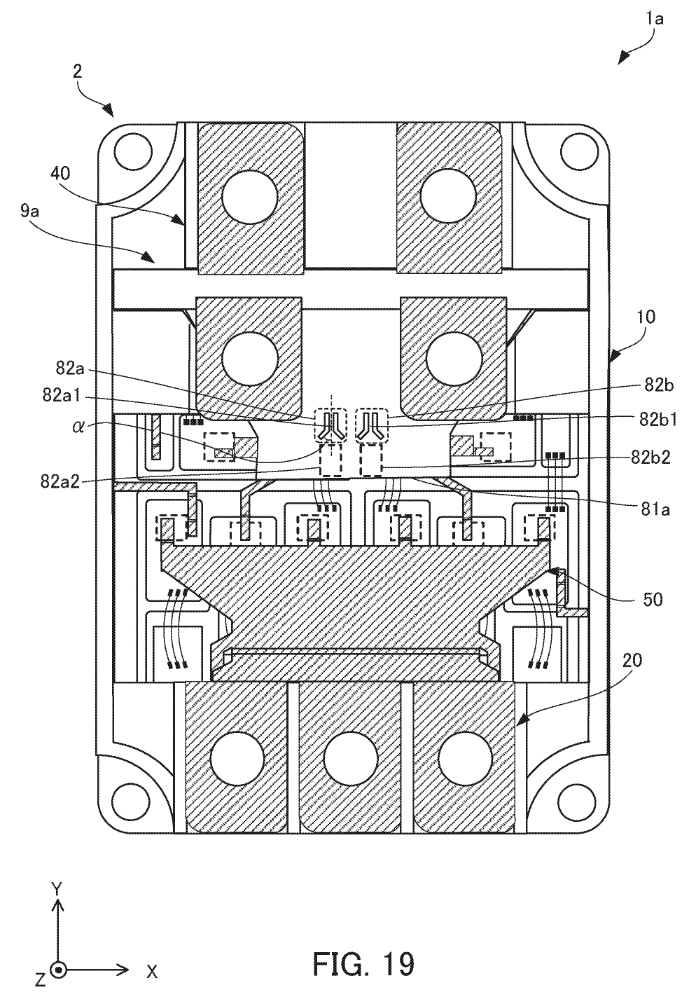

A semiconductor device according to a second embodiment differs from the semiconductor device according to the first embodiment in the regulating members 82a and 82b formed on the horizontal sealing surface 81 included in the terminal unit 9. The semiconductor device according to the second embodiment will be described with reference to FIG. 19. FIG. 19 is a plan view of the semiconductor device according to the second embodiment. FIG. 19 corresponds to FIG. 13 of the first embodiment, and the second nut housing portion 30 is not attached in FIG. 19. In addition, in the second embodiment, portions different from the first embodiment will be described.

Regulating members 82a and 82b of a terminal unit 9a included in a semiconductor device 1a according to the second embodiment are moved from an end portion 81a (in the direction of a fourth side wall 10d) of a horizontal sealing surface 81 toward a third side wall 10c. Therefore, on the horizontal sealing surface 81, there are margin regions 82a2 and 82b2 between the regulating members 82a and 82b and the end portion 81a of a sealing member 80 in plan view. Nothing is provided in the margin regions 82a2 and 82b2.

Further, openings of gaps 82a1 and 82b1 of the regulating members 82a and 82b, the openings facing the end portion 81a, are widened. An inclination angle α of one side of the gap 82a1 of the regulating member 82a may be, for example, 45° or more. Therefore, the opening angle of the gap 82a1 of the regulating member 82a is 90° or more. The regulating member 82b has the same inclination angle α and the same opening angle.

In this case, when the second nut housing portion 30 is attached, it is possible to temporarily dispose the second nut housing portion 30 in the margin regions 82a2 and 82b2 of the horizontal sealing surface 81 between the regulating members 82a and 82b and the end portion 81a. Accordingly, the second nut housing portion 30 is stabilized. Further, the openings of the gaps 82a1 and 82b1 of the regulating members 82a and 82b are widened. Therefore, it is possible to guide the second nut housing portion 30 more stably to the attachment region (region A). As described above, the assemblability of the semiconductor device 1a is further improved as compared with the first embodiment.

The disclosed technique improves the assemblability of a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first board having an upper surface;
a second board having an upper surface;
a case which includes side walls that
surround an opening in a plan view of the semiconductor device, and
include a first side wall and a second side wall each extending in a longitudinal direction,
the first board and the second board being disposed in the case sequentially in the longitudinal direction;
an external connection terminal which
has a lower end electrically connected to the second board, and
has, at an upper end thereof, an external connection portion facing the second board;
a first nut housing portion, which
is attached to the first side wall and the second side wall in a thickness direction of the case, and
is positioned above the opening and faces the first board; and
a second nut housing portion, which
is attached to the case in the longitudinal direction and located between the first side wall and the second side wall, and
is provided on the external connection portion.

2. The semiconductor device according to claim 1, wherein
the external connection terminal forms a terminal unit with a sealing member, the sealing member
sealing the external connection terminal except for the lower end thereof and the external connection portion, and
having a horizontal sealing surface facing the external connection portion with a gap therebetween,
the terminal unit being provided between the first side wall and the second side wall of the case; and
the second nut housing portion is provided in the gap between the external connection portion and the horizontal sealing surface.

3. The semiconductor device according to claim 1, further comprising a wiring member that is provided inside the side walls of the case and that is bonded to the first board.

4. The semiconductor device according to claim 1,
wherein the case further includes a first beam portion between the first side wall and the second side wall, the first beam portion having a rectangular shape in the plan view and partitioning the opening into a first opening portion and a second opening portion that are positioned side by side in the longitudinal direction,
wherein the first board is located in the first opening portion, and the second board is located in the second opening portion, in the plan view, and
wherein the first nut housing portion faces the upper surface of the first board.

5. The semiconductor device according to claim 4, wherein
the first nut housing portion includes a first attachment portion formed on a lower surface thereof,
the case further has a first attachment part provided therein, and
the first attachment portion of the first nut housing portion is attached to the first attachment part of the case in the thickness direction.

6. The semiconductor device according to claim 5, wherein one of the first attachment portion of the first nut housing portion and the first attachment part to which the first attachment portion is attached is a protrusion, and the other is a hole into which the protrusion is fitted.

7. The semiconductor device according to claim 4,
wherein each of the first side wall and the second side wall includes a positioning member on an inner side thereof, the positioning members facing each other and each extending in the longitudinal direction, and
wherein the second nut housing portion has, on a lower surface thereof, two end portions parallel to each other and each extending in the longitudinal direction, the two end portions being respectively disposed on upper surfaces of the positioning members via an adhesive.

8. The semiconductor device according to claim 7, wherein each of the positioning members has a locking member for locking the second nut housing portion.

9. The semiconductor device according to claim 8,
wherein the external connection terminal forms a terminal unit with a sealing member, the sealing member
sealing the external connection terminal except for the lower end thereof and the external connection portion, and
having a horizontal sealing surface facing the external connection portion with a gap therebetween,
the terminal unit being provided between the first side wall and the second side wall of the case,
wherein the second nut housing portion is provided in the gap between the external connection portion and the horizontal sealing surface, and
wherein the horizontal sealing surface of the sealing member has a guide portion formed thereon, for guiding the second nut housing portion moving in the longitudinal direction.

10. The semiconductor device according to claim 9,
wherein the guide portion is a regulating member having a gap extending in the longitudinal direction, and
wherein the second nut housing portion has a projection formed on the lower surface thereof, the projection being configured to pass through the gap of the regulating member.

11. The semiconductor device according to claim 10, wherein the regulating member is displaced in the longitudinal direction from an end portion of the horizontal sealing surface of the sealing member of the terminal unit.

12. The semiconductor device according to claim 10, wherein an opening of the gap of the regulating member facing an end portion of the horizontal sealing surface is widened.

13. A semiconductor device, comprising:
a first board having an upper surface;
a second board having an upper surface larger in area than the upper surface of the first board;
a case which includes side walls that
surround an opening in a plan view of the semiconductor device, and
include a first side wall and a second side wall each extending in a longitudinal direction,
the first board and the second board being disposed in the case sequentially in the longitudinal direction;
a nut housing portion which
is attached to the first side wall and the second side wall, and
is positioned above the opening and faces the first board; and
a wiring member which has a lower end bonded to the upper surface of the first board and which is housed in the case.

14. The semiconductor device according to claim 13, wherein the lower end of the wiring member is bonded to the upper surface of the first board by ultrasonic bonding, laser welding, or via a sintered material.

15. A semiconductor device, comprising:
a board which includes an upper surface;
a case which includes side walls that
surround an opening in a plan view of the semiconductor device, and
include a first side wall and a second side wall extending in a longitudinal direction,
the case housing the board;
a terminal unit which includes
an external connection terminal that
has a lower end electrically connected to the board, and
has, at an upper end thereof, an external connection portion facing the board, and
a sealing member that
seals the external connection terminal except for the lower end thereof and the external connection portion, and
includes a horizontal sealing surface facing the external connection portion with a gap therebetween,
the terminal unit being provided between the first side wall and the second side wall of the case; and
a nut housing portion which is attached to the case in the longitudinal direction and is provided in the gap between the external connection portion and the horizontal sealing surface,
wherein the horizontal sealing surface of the sealing member has a guide portion formed thereon, for guiding the nut housing portion in the longitudinal direction.
